(19) United States
(12) Patent Application Publication
(10) Pub. No.: US 2012/0028375 A1
(43) Pub. Date: Feb. 2, 2012

(54) INSPECTION METHOD OF LIGHT-EMITTING DEVICE AND PROCESSING METHOD AFTER INSPECTION OF LIGHT-EMITTING DEVICE

(75) Inventors: Satoshi SATO, Osaka (JP); Hisataka ITO, Osaka (JP); Yasunari OOYABU, Osaka (JP)

(73) Assignee: NITTO DENKO CORPORATION, Osaka (JP)

(21) Appl. No.: 13/190,738

(22) Filed: Jul. 26, 2011

(30) Foreign Application Priority Data
Jul. 27, 2010 (JP) P2010-168315

(51) Int. Cl. H01L 21/66; G01R 31/00

(52) U.S. Cl. 438/4; 438/17; 324/414; 438/26; 257/E21.529; 257/E21.525

(57) ABSTRACT

The present invention relates to a method for inspecting a light-emitting device, the method including performing a light emission test of (A) a light-emitting device including a lead frame having mounted and packaged thereon a plurality of light-emitting elements or (B) a light-emitting device obtained by resin encapsulating and packaging the light-emitting device (A), by applying a current to the plurality of light-emitting elements and judging each light-emitting element as passed or failed, in which arrangement of the plurality of light-emitting elements in the light-emitting device is set as in the following (α): (α) In a lead frame having a lattice form including a plurality of rows and a plurality of columns with a plurality of intersection points formed thereby, a plurality of light-emitting elements are disposed between the adjacent intersection points in each row, the adjacent light-emitting elements in each row are connected to each other so that positive electrode terminals or negative electrode terminals thereof face each other, and a positive-side power supply channel or a negative-side power-supply channel in the lead frame works as a common channel between a certain column and a column adjacent thereto.

### FIELD OF THE INVENTION

The present invention relates to a method for inspecting a light-emitting device using a light-emitting element such as LED and relates to a processing method after inspection of the light-emitting device.

### BACKGROUND OF THE INVENTION

Conventionally, for energy saving of devices, a light-emitting device using a light-emitting element such as light-emitting diode (hereinafter referred to as “LED”) has been employed as a light source (backlight) of a liquid crystal display panel such as liquid crystal TV, liquid crystal display and liquid crystal monitor.

As for the light-emitting element substrate such as LED substrate used for the light-emitting device, a large number of light-emitting elements (LED elements) are disposed in an array on a substrate having provided thereon a reflector including an insulating resin and after electrically connecting (packaging) these light-emitting elements by wire bonding or the like, the packaged light-emitting elements are encapsulated with an encapsulating resin and individualized by dicing to produce a discrete-type package having one or a plurality of light-emitting elements. All of the obtained discrete-type packages are subjected to a light emission test, and only a non-defective product passed the test is used for secondary packaging on a main substrate (large substrate) of a light-emitting device (see, Patent Documents 1 to 3).

Patent Document 1: JP-A-2004-186488

Patent Document 2: JP-A-2009-21394

Patent Document 3: JP-A-2007-65414

### SUMMARY OF THE INVENTION

However, when a method of secondarily packaging the above-described discrete-type package is used for the manufacture of a light-emitting device, the inspection therefor disadvantageously takes much time, because the discrete-type packages are tested for light emission one by one.

Furthermore, when fabricating a final light-emitting device through secondary packaging by combining the above-described discrete-type packages, it is required to adjust the luminance, color temperature or the like of each discrete-type package and keep the luminance or the like as an entire light-emitting device within the predetermined range. Also here, time and labor are used for again performing a light emission test. Improvement thereof has been demanded.

The present invention has been made under these circumstances, and an object of the present invention is to provide a method for inspecting a light-emitting device with good working efficiency and a processing method after inspection of the light-emitting device.

Namely, the present invention relates to the following items (1) to (3).

(1) A method for inspecting a light-emitting device, the method including performing a light emission test of (A) a light-emitting device including a lead frame having mounted and packaged thereon a plurality of light-emitting elements or (B) a light-emitting device obtained by resin encapsulating and packaging the light-emitting device (A), by applying a current to the plurality of light-emitting elements and judging each light-emitting element as passed or failed,

in which arrangement of the plurality of light-emitting elements in the light-emitting device is set as in the following (α):

(α) In a lead frame having a lattice form including a plurality of rows and a plurality of columns with a plurality of intersection points formed thereby, a plurality of light-emitting elements are disposed between the adjacent intersection points in each row,

the adjacent light-emitting elements in each row are connected to each other so that positive electrode terminals or negative electrode terminals thereof face each other, and

a positive-side power supply channel or a negative-side power-supply channel in the lead frame works as a common channel between a certain column and a column adjacent thereto.

(2) A processing method after inspection of a light-emitting device, in which a non-defective portion of the light-emitting device (A) or (B) judged as defective by the inspection method according to claim 1 is separated by cutting and reused.

(3) A processing method after inspection of a light-emitting device, in which a light-emitting device (A) judged as non-defective by the inspection method according to claim 1 is encapsulated with a resin and packaged to be finished as a product.

That is, as a result of continued intensive and extensive investigations to attain the object above, the present inventors have conceived of an idea that, in a light emission test of (A) a light-emitting device including a lead frame having mounted and packaged thereon a plurality of light-emitting elements or (B) a light-emitting device obtained through resin encapsulation and packaging of the light-emitting device above, a light emission test is performed on the lead frame basis without cutting and separating each light-emitting element packaged in a grid pattern on a lead frame. The experiments were repeated, and it has been found that, in a lead frame having a lattice form including a plurality of rows and a plurality of columns with a plurality of intersection points formed thereby, a plurality of light-emitting elements are disposed between the adjacent intersection points in each row; the adjacent light-emitting elements in each row are connected to each other so that positive electrode terminals or negative electrode terminals thereof face each other; and a positive-side power supply channel or a negative-side power-supply channel in the lead frame works as a common channel between a certain column and a column adjacent thereto, thereby being able to perform the above-described light emission test en bloc on the lead frame basis. The present invention has been achieved based on this finding.

In the inspection method of a light-emitting device of the present invention, in a lead frame having a lattice form including a plurality of rows and a plurality of columns with a plurality of intersection points formed thereby, a plurality of light-emitting elements are disposed between the adjacent intersection points in each row; the adjacent light-emitting elements in each row are connected to each other so that positive electrode terminals or negative electrode terminals thereof face each other; and a positive-side power supply channel or a negative-side power-supply channel in the lead frame works as a common channel between a certain column and a column adjacent thereto. Accordingly, in the inspection method of a light-emitting device, a light emission test can be performed on the basis of the above-described lead frame without individually separating the light-emitting elements and enhancement of the working efficiency and reduction in the required time can be achieved in the light emission test. This inspection method is also advantageous in that only a lead frame passed the light emission test is delivered to the processing step of a light-emitting device and therefore, materials and man-hours are not wasted.

Furthermore, with respect to the light-emitting devices (A) and (B) judged as defective by the inspection method, in the case where the non-defective portion of such a light-emitting device is separated by cutting and reused, the usable non-defective portion is not wasted and materials discarded in the processing after inspection of a light-emitting device can be reduced.

In addition, with respect to the light-emitting device (A) judged as non-defective by the inspection method, in the case where it is finished as a product through resin encapsulation and packaging, the light-emitting device (A) can be as-is utilized as a multichip-type light-emitting element package, whereby a product configuration based on the luminance, color temperature and the like on the package basis becomes possible. Also, labors or man-hours involved in the conventional discrete configuration can be reduced and at the same time, the productivity is enhanced in comparison with the manufacturing method involving conventional secondary packaging.

### BRIEF DESCRIPTION OF THE DRAWINGS

FIGS. 1A and 1B are views for explaining the outline of the inspection method of a light-emitting device in the embodiment of the present invention.

FIGS. 2A to 2C are views showing configuration examples of the package form in the processing method after inspection of the light-emitting device above.

FIG. 3 is a view showing the profile of a lead frame used for the inspection method of light-emitting device in the embodiment of the present invention.

FIG. 4 is a view showing the state after light-emitting element packaging of the lead frame above.

FIGS. 5A to 5D are views for explaining the inspection method of a light-emitting device and the processing method after inspection according to the embodiments of the present invention.

### DETAILED DESCRIPTION OF THE INVENTION

The mode for carrying out the present invention is described in detail below by referring to the drawings.

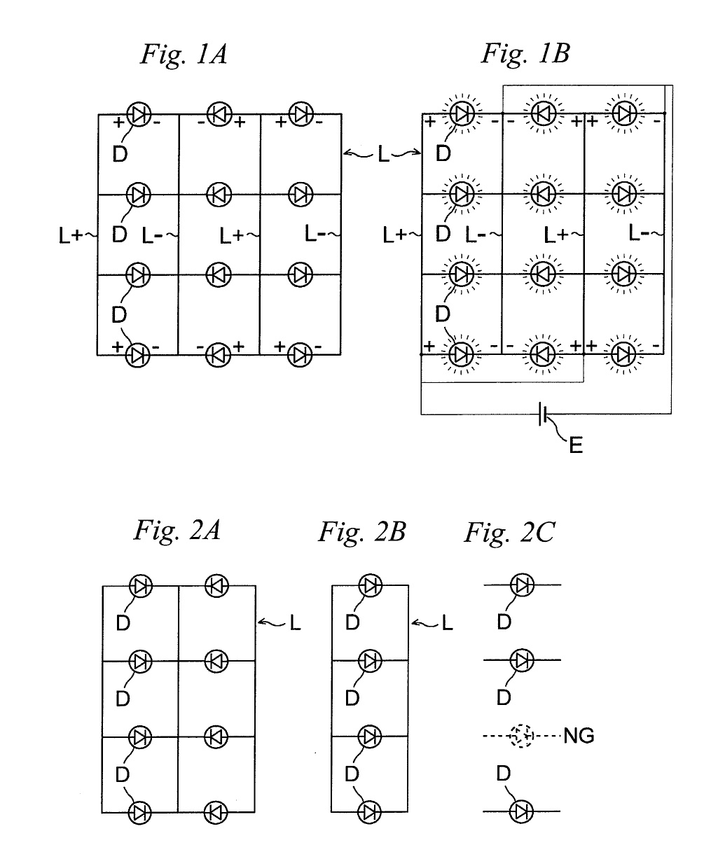

FIGS. 1A and 1B are circuit diagrams for explaining the outline of the inspection method of a light-emitting device in the embodiment of the present invention. In the figures, symbol D indicates LED packaged and put into a state capable of emitting light, and symbols + and − denote the positive electrode terminal side and the negative electrode terminal side of the LED.

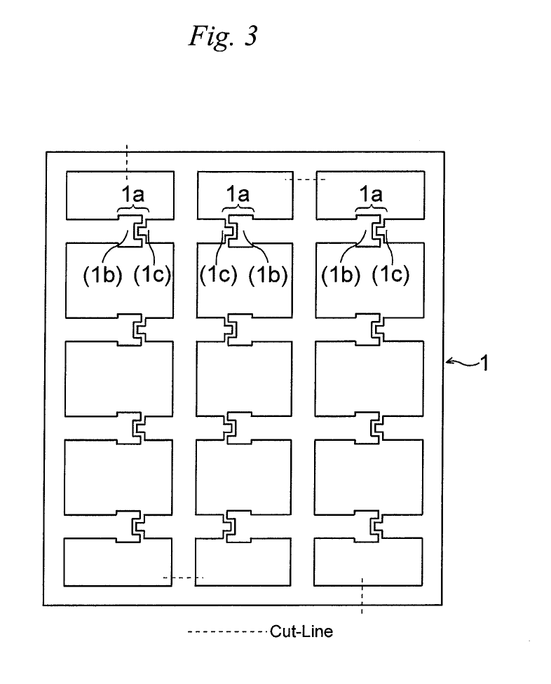

The light-emitting device to be inspected in this embodiment is (A) a light-emitting device including a lead frame L having mounted and packaged thereon a plurality of light-emitting elements (LED; symbol D) or (B) a light-emitting device obtained through resin encapsulation and packaging of the light-emitting device above, where, as shown in FIG. 1A, LEDs (D) are disposed at predetermined positions (respective electrode sites) of a lead frame (see, FIG. 3) in a grid pattern consisting of rows and columns and electrically connected (packaged) by wire bonding or the like.

In the lead frame L, a plurality of columns (in this example, three columns in the transverse direction) each having a plurality of LEDs (D) (in this example, four LEDs in the longitudinal direction) are disposed, and the adjacent light-emitting elements in each row are connected to each other so that positive electrode terminals or negative electrode terminals thereof face each other (namely, connections of respective LEDs (D) between adjacent columns are oriented in the inverse direction). That is, in FIG. 1A, the leftmost LED column and the central LED column are in a “face-to-face arrangement” where the positive electrode terminals or negative electrode terminals of LEDs (D) between adjacent columns face each other (the same applies to between the central LED column and the rightmost LED column). And, this lead frame is configured such that the positive-side power-supply channel L+ or the negative-side power-supply channel L− works as a common channel between a certain column and a column adjacent thereto and, as shown in FIG. 1B, when a power source E is connected to a predetermined position, these LEDs (D) can be lighted all together.

Thanks to this configuration, the inspection method of a light-emitting device in this embodiment makes it possible to perform a light emission test on the lead frame L basis without individually cutting and separating the LEDs (D). In turn, the time required for the light emission test can be reduced and at the same time, the working efficiency of the test can be enhanced.

In the case of back-to-back arrangement where connections of respective LEDs are oriented in the same direction between adjacent columns, a pair of a positive-side power-supply channel and a negative-side power-supply channel need to be provided between respective columns, but in the light-emitting device of this embodiment, as described above, connections of respective LEDs are oriented in the “face-to-face arrangement” and this is advantageous in that by using a common channel for the positive-side power-supply channel and the negative-side power-supply channel, labors or the like for wiring as well as the area necessary for wiring can be reduced and the lead frame can be made small.

The processing method of the light-emitting device after the light emission test is described below.

Out of light-emitting devices passed the light emission test, (B) a package already encapsulated with a resin is as-is utilized as a product after the light emission test or, as described above, used for secondary packaging on a main substrate of a larger light-emitting device.

Also, out of the light-emitting devices passed the light-emission test, (A) a light-emitting device not encapsulated with a resin is, after encapsulating LED with an encapsulating resin, similarly to (B) above, as-is utilized as a product or used for secondary packaging on a main substrate of a large light-emitting device.

On the other hand, as for the light-emitting device failed the light emission test (judged as defective), as shown in FIGS. 2A to 2C, the non-defective portion is separated by cutting and after removing the defective portion (defective LED), the remaining non-defective portion is used as a product.

For example, in the embodiment above, when one LED out of light-emitting elements is judged as defective, the defective LED is separated by dicing, whereby the package can be utilized as a medium-size package (see, FIG. 2A) smaller than the large package passed the light emission test, a small package having one column (FIG. 2B), or a discrete-type package (see, FIG. 2C) obtained by individualization of such a package.

In this way, when a light-emitting device judged as passed by the inspection method above is utilized as a multichip-type light-emitting element package, labors or man-hours involved in conventional discrete configuration can be reduced and the productivity is enhanced.

Also, in the case where the non-defective portions of a light-emitting device judged as defective by the inspection method above are individualized by cutting and reused, the usable non-defective portion is not wasted and materials discarded in the processing after inspection can be reduced.

The embodiment is more specifically described below by referring to the drawings.

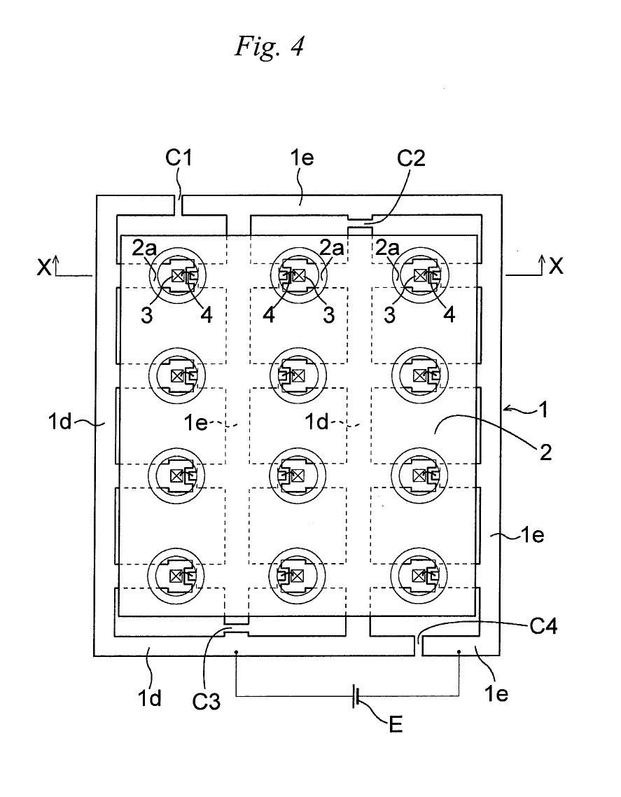

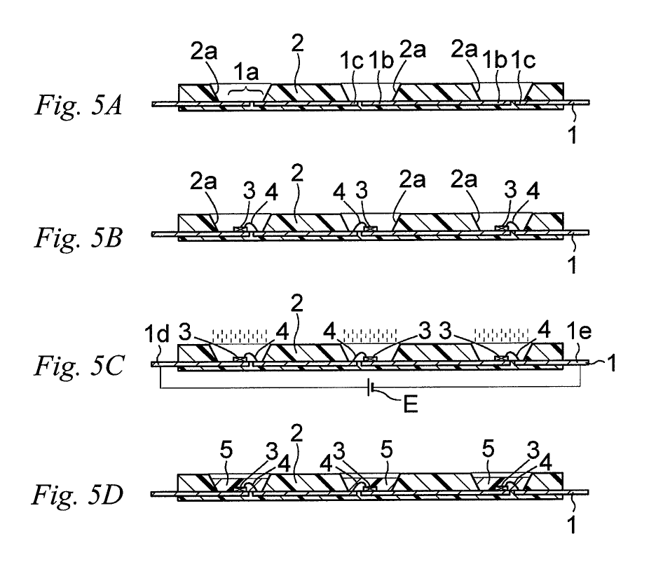

FIG. 3 is a plan view showing the profile of a lead frame used for the inspection method of a light-emitting device of this embodiment, and FIG. 4 is a view showing the state after light-emitting element packaging of the lead frame above. FIGS. 5A to 5D are views for explaining the inspection method of a light-emitting device in sequence of steps. Incidentally, FIGS. 5A to 5D each corresponds to the cross-sectional view along line X-X of FIG. 4. In the figures, symbol 1 indicates a lead frame, 2 indicates a resin-made insulator, 2a indicates a reflector member, 3 indicates a bare chip of LED, 4 indicates a bonding wire, 5 indicates an encapsulating resin, and C1 to C4 indicate cutting sites of the lead frame 1.

The inspection method of a light-emitting device in this specific embodiment is performed by the same procedure as in the above-described inspection method, where LED bare chips (hereinafter, LED) 3 are packaged on a lead frame 1 (FIG. 5B), a light emission test is performed by applying a current (power supply) to the lead frame 1 (FIG. 5C), and inspection (judgment of pass or fail) of luminance, color temperature or the like is performed on the basis of the lead frame above. This is described in detail below.

The lead frame 1 used for the inspection method of a light-emitting element is formed from a metal-made thin plate (electrically conductive material) by a punching method, an etching method or the like. The profile thereof is such that, as shown in the plan view of FIG. 3, a plurality of columns (in this example, three columns in the transverse direction) each having a column of electrode parts 1a (in this example, four electrode parts in the longitudinal direction) supported by a pillar frame are formed within a frame (outer frame) supporting the entirety.

As seen from the figures, out of three columns in the transverse direction, the electrode part 1a in the central longitudinal column is designed in a “face-to-face arrangement” where arrangement of the positive electrode side (1b) and the negative electrode side (1c) is opposite the arrangement for the electrode part 1a in the leftmost or rightmost longitudinal column adjacent thereto. And, the lead frame 1 is configured such that by cutting it along the cut-line denoted by a dotted line, the later-described positive-side power-supply channel and the negative-side power-supply channel are formed and power can be supplied through these lead frames 1.

Production of a light-emitting device by using such a lead frame 1 is performed as follows. First, as shown in FIG. 5A, an insulator 2 is formed on the lead frame 1 by using a transfer molding machine or the like. The insulator 2 has, in the periphery of each electrode part 1a, a recessed reflector member 2a reflecting light of LED 3. The recessed part of the reflector member 2a works out to an LED element 3-housing part and at the same time, fulfills a role as a dam, a dike or the like to prevent outflow of the later-described encapsulating resin 5.

Subsequently, as shown in FIG. 5B, each LED 3 is bonded (die-bonded) on the electrode part 1a by using an electrically conductive paste or the like, and the LEDs 3 are electrically connected (packaged) through a bonding wire 4 such as gold wire by using a wire bonding machine.

Thereafter, the lead frame 1 is cut at cut-line (see, doted line in FIG. 3) portions by a dicing method or the like, whereby, as shown in the plan view of FIG. 4, a positive-side pure-supply channel 1d and a negative-side power-supply channel 1e are formed by the lead frame 1. These positive-side power-supply channel 1d and negative-side power-supply channel 1e are served by a common channel between a certain column and a column adjacent thereto and by the cutting above, respective LEDs 3 on the lead frame 1 are put into a state of being electrically connected in parallel. Then, a power source E is connected to one appropriate position of each of the positive-side power-supply channel 1d and the negative-side power-supply channel 1e, as a result, a current can be supplied at a time to all LEDs 3 on the lead frame 1.

Incidentally, such a common power-supply channel can be realized thanks to the “face-to-face arrangement” of LED columns. Also, a power-supply channel (either one of a positive-side power-supply channel 1d and a negative-side power-supply channel 1e) between respective LED columns is shared in common between adjacent LED columns and therefore, it is not necessary to “doubly” provide the positive-side power-supply channel 1d and the negative-side power-supply channel 1e between these LED columns. In turn, the lead frame 1 need not provide an extra space (width) for laying two power-supply channels (wirings) between adjacent LED columns and is configured to be small in the size and area.

The subsequent light emission test of the light-emitting device is performed, as shown in FIG. 4 and FIG. 5C, by connecting the positive electrode of the power source E to the positive-side power-supply channel 1d joined to the + side terminal of each LED 3 and at the same time, connecting the negative electrode of the power source E to the negative-side power-supply channel 1e joined to the − side terminal of each LED 3, thereby lighting respective LEDs 3 at the same time.

Measurement of light emitted from each LED 3 is performed on the basis of the lead frame 1 above. In the measurement, for example, an actinometer using a photodiode, CCD, C-MOS or the like, a photometer, a spectral analyzer, or an image sensor can be employed. Also, for averaging the light emitted from a plurality of LEDs 3, a diffuser plate or the like may be disposed between the probe of the optical measuring instrument above and the lead frame 1. The judgment of pass or fail is performed by determining whether or not the light quality (luminance), color temperature (wavelength) and the like fall within the predetermined criteria. Only a lead frame 1 passed the light emission test (inspection) is allowed to proceed to the next step.

In the lead frame 1 passed the light emission test, as shown in FIG. 5D, a predetermined amount of an encapsulating resin 5 is dropped (potting) on each LED 3 (in a space of the recess part surrounded by the reflector member 2a) and cured by radiation irradiation, heating or the like to effect encapsulating, whereby a multichip-type package product (large package) is completed. This large package is then used directly as a product or utilized for secondary packaging on a main substrate of a larger light-emitting device.

On the other hand, in a lead frame 1 rejected for the failure in meeting the criteria in the light emission test, LEDs 3 are individually measured for luminance, color temperature and the like, and the results are recorded. Thereafter, the lead frame 1 is cut by a dicing apparatus or the like at the pillar part connecting respective LEDs 3 in a grid pattern, thereby producing a smaller medium-size package (see, FIG. 2A), a small package having one column (FIG. 2B), or a discrete-type package (see, FIG. 2C) obtained by individualization of such a package, and each LED 3 is encapsulated with an encapsulating resin 5, similarly to the lead frame 1 passed the light emission test.

In this way, according to the inspection method of a light-emitting device of this embodiment, the light emission test can be performed on the lead frame 1 basis without individually cutting and separating respective LEDs 3 as in conventional methods, whereby in the light-emission test, the required time is reduced and the working efficiency is enhanced.

Also, according to the processing method after inspection of a light-emitting device of this embodiment, once LED 3 is encapsulated, the lead frame 1 passed the light emission test can be directly used for secondary packaging on a main substrate of a large light-emitting device.

Furthermore, according to the processing method after inspection of a light-emitting device of this embodiment, even when one LED 3 out of respective LEDs 3 is defective, the non-defective portion thereof can be separated by cutting and reused without discarding the entire package. Accordingly, materials discarded in the processing after inspection of a light-emitting device can be reduced. In addition, according to the processing method after inspection of a light-emitting device, the light-emitting elements, other members, man-hours spent for their manufacture, and the like are not wasted, and the cost of the product package can be reduced.

As the material constituting the insulator 2, an insulating thermoplastic resin or thermosetting resin can be used. Above all, a silicone resin excellent in the heat resistance is preferred, and a thermosetting addition-reactive silicone resin having a structure where either a vinyl group or an ally! group and a hydrogen atom are bonded directly to a silicon atom, is more preferred. The resin constituting the insulator 2 contains a white pigment (e.g., titanium oxide) for increasing the light reflectance.

The encapsulating resin 5 for encapsulating LED 3 includes, for example, an epoxy or silicone resin having light transparency. Such an encapsulating resin 5 may contain a fluorescent material or the like.

The LED 3 above is preferably a blue LED or an ultraviolet LED, where white color or visible light is obtained through wavelength conversion by the fluorescent material.

### EXAMPLES

Working examples are described below, but the present invention is not limited to the following Examples.

### Example 1

A copper-made plate material whose surface is plated with silver was punched into a predetermined shape (see, FIG. 3), thereby preparing a lead frame, and a bare chip of blue LED (SL-V-B15AA, manufactured by SEMILEDS) was die-bonded to each electrode part (a longitudinal column of four electrode parts×three columns in the transverse direction) of the prepared lead frame by using a silver paste. Thereafter, the chips were packaged by wire bonding using a gold wire, and the lead frame was cut by a dicing apparatus at the positions of Cut-Line shown in FIG. 3 to form a positive-side power-supply channel and a negative-side power-supply channel, whereby a lead frame for light emission test was produced.

Subsequently, a positive electrode and a negative electrode of a power supply were connected to the positive-side power-supply channel and the negative-side power-supply channel, respectively, of the lead frame above and in a state of lighting each blue LED, the emission wavelength was measured using a spectrophotometer (MCPD-7000, manufactured by Otsuka Electronics Co., Ltd.). The acceptance criterion in the test was the reference wavelength ±10 nm.

Thereafter, a silicone elastomer (LR7665, produced by Wacker Asahikasei Silicone Co., Ltd.) was dropped in each electrode part (on the blue LED) of the lead frame passed the test and cured to encapsulate the blue LED. In this way, the light-emitting element package of Example 1 was obtained.

### Example 2

The lead frame of Example 2 was obtained in the same manner as in Example 1 except that before packaging bare chips of blue LED, a white reflector was previously formed by transfer molding.

The transfer molding of the white reflector was performed using a resin composition containing the following components (i) to (iii):

(i) a thermosetting addition-reactive silicone resin having a structure where either a vinyl group or an allyl group and a hydrogen atom are bonded directly to a silicon atom,

(ii) a platinum-based catalyst as a curing catalyst for the component (i), and

(iii) a white pigment.

Using the lead frames obtained in Examples 1 and 2, a light emission test was performed on the basis of each lead frame. In this light emission test, the inspection was performed on the lead frame basis without separating the lead frame into individual LEDs and therefore, the required time of the emission test was greatly reduced.

While the invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2010-168315 filed on Jul. 27, 2010, and the contents are incorporated herein by reference.

All references cited herein are incorporated by reference herein in their entirety.

Also, all the references cited herein are incorporated as a whole.

The present invention is suitable for inspection of a light-emitting device such as backlight or LED bulb using a light-emitting element (e.g., LED), where light-emitting elements are packaged on a lead frame.

### Description of Reference Numerals and Signs

D Light-emitting element (LED)

L Lead frame

L+ Positive-side power-supply channel

L− Negative-side power-supply channel

What is claimed is:

1. A method for inspecting a light-emitting device, the method comprising performing a light emission test of (A) a light-emitting device comprising a lead frame having mounted and packaged thereon a plurality of light-emitting elements or (B) a light-emitting device obtained by resin encapsulating and packaging the light-emitting device (A), by applying a current to the plurality of light-emitting elements and judging each light-emitting element as passed or failed, wherein arrangement of the plurality of light-emitting elements in the light-emitting device is set as in the following (α):
(α) In a lead frame having a lattice form comprising a plurality of rows and a plurality of columns with a plurality of intersection points formed thereby, a plurality of light-emitting elements are disposed between the adjacent intersection points in each row,
the adjacent light-emitting elements in each row are connected to each other so that positive electrode terminals or negative electrode terminals thereof face each other, and
a positive-side power supply channel or a negative-side power-supply channel in the lead frame works as a common channel between a certain column and a column adjacent thereto.

2. A processing method after inspection of a light-emitting device, wherein a non-defective portion of the light-emitting device (A) or (B) judged as defective by the inspection method according to claim 1 is separated by cutting and reused.

3. A processing method after inspection of a light-emitting device, wherein a light-emitting device (A) judged as non-defective by the inspection method according to claim 1 is encapsulated with a resin and packaged to be finished as a product.
